(19) United States
(12) Patent Application Publication
(10) Pub. No.: US 2026/0112431 A1
(43) Pub. Date: Apr. 23, 2026

(54) OTP MEMORY DEVICE AND OTP MEMORY CELL HAVING MULTIPLE PROGRAM TRANSISTORS

(71) Applicant: Samsung Electronics Co., Ltd., Suwon-si (KR)

(72) Inventors: Seokhyeon YOON, Suwon-si (KR); Gibum KIM, Suwon-si (KR); Dasom JEONG, Suwon-si (KR)

(73) Assignee: Samsung Electronics Co., Ltd., Suwon-si (KR)

(21) Appl. No.: 19/327,666

(22) Filed: Sep. 12, 2025

(30) Foreign Application Priority Data
Oct. 18, 2024 (KR) 10-2024-0143266

(51) Int. Cl. G11C 17/14; G11C 5/06; G11C 17/16; G11C 17/18

(52) U.S. Cl. CPC G11C 17/146; G11C 5/063; G11C 17/16; G11C 17/18

(57) ABSTRACT

Disclosed are a one-time-programmable (OTP) memory device and an OTP memory cell having multiple program transistors. The OTP memory device may include a plurality of OTP memory cells, wherein each of the plurality of OTP memory cells may include a first program transistor having a first breakdown voltage, a second program transistor having a second breakdown voltage, and a read transistor connected to the first program transistor and the second program transistor. Each of the first program transistor, the second program transistor and the read transistor may include a fin-type active region extending in a first direction on a substrate. A first fin-type active region of the first program transistor, a second fin-type active region of the second program transistor, and a third fin-type active region of the read transistor may be separated from each other.

### CROSS-REFERENCE TO RELATED APPLICATION

This application is based on and claims priority under 35 U.S.C. § 119 to Korean Patent Application No. 10-2024-0143266, filed on Oct. 18, 2024 in the Korean Intellectual Property Office, the disclosure of which is incorporated by reference herein in its entirety.

### BACKGROUND

Inventive concepts relate to semiconductor memory devices, and more particularly, to a one-time-programmable (OTP) memory cell including multiple program transistors and an OTP memory device including the same, to improve the distribution of the breakdown voltage of OTP memory cells.

Since integrated circuits (ICs) have data storage functions, memory devices are one of the main members. In the field of embedded non-volatile memory, OTP memory with an antifuse structure is widely used. Since the OTP memory has high stability, is fully compatible with the complementary metal oxide semiconductor (CMOS) process, and is easy to program, the OTP memory may be used in analog circuit trimming, secure code and chip identification (ID) storage, static random access memory (SRAM)/dynamic random access memory (DRAM) redundancy design, and/or radio frequency identification (RFID). Additionally, the OTP memory non-volatile logic intellectual property (IP) core may be applied to system-on-chip (SoC) and/or Internet Of Things (IoT) chips. Accordingly, the OTP memory is becoming increasingly important to chip performance. Among the characteristic distributions of OTP memory cells, breakdown voltage distribution may be an important factor in determining chip performance.

### SUMMARY

Inventive concepts provide a one-time-programmable (OTP) memory cell including multiple program transistors and an OTP memory device including the same, to improve the distribution of the breakdown voltage of OTP memory cells.

According to an embodiment of inventive concepts, a one-time-programmable (OTP) memory device and an OTP memory cell may have multiple program transistors. The OTP memory device may include a plurality of OTP memory cells on a substrate. Each of the plurality of OTP memory cells may include a first program transistor having a first breakdown voltage, a second program transistor having a second breakdown voltage, and a read transistor connected to the first program transistor and the second program transistor. Each of the read transistor, the first program transistor, and the second program transistor may include a fin-type active region extending in a first direction on the substrate, a plurality of semiconductor patterns spaced apart from an upper surface of the fin-type active region and having a channel region, and a gate electrode extending in a second direction on the fin-type active region and arranged between each of the plurality of semiconductor patterns. The second direction may intersect the first direction. The fin-type active region of the first program transistor may be a first fin-type active region. The fin-type active region of the second program transistor may be a second fin-type active region. The fin-type active region of the read transistor may be a third fin-type active region. The first fin-type active region of the first program transistor, the second fin-type active region of the second program transistor, and the third fin-type active region of the read transistor may be separated from each other.

According to an embodiment of inventive concepts, an OTP memory device may include a plurality of OTP memory cells on a substrate. Each of the plurality of OTP memory cells may include a first program transistor having a first breakdown voltage, a second program transistor having a second breakdown voltage, and a read transistor connected to the first program transistor and the second program transistor. Each of the read transistor, the first program transistor, and the second program transistor may include a fin-type active region extending in a first direction on the substrate, a plurality of semiconductor patterns spaced apart from an upper surface of the fin-type active region and having a channel region, and a gate electrode extending in a second direction on the fin-type active region and arranged between each of the plurality of semiconductor patterns. The second direction may intersect the first direction. Each of the plurality of OTP memory cells may be configured to be programmed by a lower voltage among the first breakdown voltage and the second breakdown voltage.

According to an embodiment of inventive concepts, a method of manufacturing a one-time programmable (OTP) memory device may include forming a device isolation trench in a first surface of a substrate, the device isolation trench defining fin-type active regions in the substrate, the fin-type active regions extending in a first direction and being spaced apart from each other in a second direction; forming a device isolation film covering sidewalls of the fin-type active regions; and forming a memory cell array on the fin-type active regions of the substrate and the device isolation film. The memory cell array may include a plurality of OTP memory cells and each of the plurality of OTP memory cells may include a first program transistor having a first breakdown voltage, a second program transistor having a second breakdown voltage, and a read transistor connected to the first program transistor and the second program transistor. Each of the read transistor, the first program transistor, and the second program transistor may include a corresponding one of the fin-type active regions, a plurality of semiconductor patterns spaced apart from an upper surface of the corresponding one of the fin-type active regions and having a channel region, and a gate electrode extending in a second direction on the corresponding one of the fin-type active regions. The second direction may intersect the first direction. The fin-type active region of the first program transistor may be a first fin-type active region. The fin-type active region of the second program transistor may be a second fin-type active region. The fin-type active region of the read transistor may be a third fin-type active region. The first fin-type active region of the first program transistor, the second fin-type active region of the second program transistor, and the third fin-type active region of the read transistor may be separated from each other.

In some embodiments, in the method, the gate electrode of the first program transistor may be a first gate electrode, the gate electrode of the second program transistor may be a second gate electrode, the gate electrode of the read transistor may be a third gate electrode. The first program transistor may include the first gate electrode, a first source electrode connected to a first source region, and a first drain electrode connected to a first drain region. The second program transistor may include the second gate electrode, a second source electrode connected to a second source region, and a second drain electrode connected to a second drain region. The read transistor may include the third gate electrode, a third source electrode connected to a third source region, and a third drain electrode connected to a third drain region. The first gate electrode and the second gate electrode may be connected to each other, and the first source electrode and the second source electrode may be connected to each other.

In some embodiments, in the method, the memory cell array may further include a plurality of first contacts on the substrate over the plurality of OTP memory cells, a plurality of second contacts on the substrate over the plurality of OTP memory cells, a voltage word line, a read word line, and a bit line. The plurality of first contacts may be spaced apart from each other and may extend in the second direction. The plurality of second contacts may be spaced apart from each other and may extend in the second direction. A first one of the plurality of first contacts may be electrically connected to the first source region of the first program transistor and the second source region of the second program transistor. A second one of the plurality of first contacts may be electrically connected to the first drain region of the first program transistor and the second drain region of the second program transistor. The voltage word line may be electrically connected to the first gate electrode of the first program transistor and the second gate electrode of the second program transistor through corresponding second contacts among the plurality of second contacts. The read word line may be electrically connected to the third gate electrode of the read transistor through one of the plurality of second contacts. The third drain electrode of the read transistor may be electrically connected to the first source electrode of the first program transistor and the second source electrode of the second program transistor. The third source electrode of the read transistor may be electrically connected to the bit line through one of the plurality of first contacts. The voltage word line may be connected to the first gate electrode and the second gate electrode.

In some embodiments, in the method, each of the plurality of OTP memory cells may further include a third program transistor having a third breakdown voltage, and the voltage word line may be electrically connected to a gate of the third program transistor.

In some embodiments, in the method, the first program transistor, the second program transistor, and the read transistor each may include a N-type metal oxide semiconductor (NMOS) transistor.

According to an embodiment of inventive concepts, a computing system may include a host processor; and a device. The host processor and the device may be configured to communicate with each other through a link. The host processor, the device, or both the host processor and the device may include a one-time-programmable (OTP) memory device having a plurality of OTP memory cells on a substrate. Each of the plurality of OTP memory cells may include a first program transistor having a first breakdown voltage, a second program transistor having a second breakdown voltage, and a read transistor connected to the first program transistor and the second program transistor. Each of the read transistor, the first program transistor, and the second program transistor may include a fin-type active region extending in a first direction on the substrate, a plurality of semiconductor patterns spaced apart from an upper surface of the fin-type active region and having a channel region, and a gate electrode extending in a second direction on the fin-type active region and arranged between each of the plurality of semiconductor patterns. The second direction may intersect the first direction. The fin-type active region of the first program transistor may be a first fin-type active region, the fin-type active region of the second program transistor may be a second fin-type active region, and the fin-type active region of the read transistor may be a third fin-type active region. The first fin-type active region of the first program transistor, the second fin-type active region of the second program transistor, and the third fin-type active region of the read transistor may be separated from each other.

In some embodiments, the host processor includes the OTP memory device.

In some embodiments, the device includes the OTP memory device.

In some embodiments, both the host processor and the device include the OTP memory device.

In some embodiments, the computing system may further include a host memory connected to the host processor; and a device memory connected to the device.

### BRIEF DESCRIPTION OF THE DRAWINGS

Embodiments will be more clearly understood from the following detailed description taken in conjunction with the accompanying drawings in which:

FIG. 1 is a conceptual diagram of a system according to some embodiments;

FIG. 2 is a block diagram of a one-time-programmable (OTP) memory device according to some embodiments;

FIGS. 3A to 3C are circuit diagrams of an OTP memory cell included in a memory cell array in FIG. 2;

FIG. 4 is a diagram illustrating the relationship between operating voltages of the OTP memory cell of FIG. 3A;

FIG. 5 is a circuit diagram of a memory cell array in FIG. 2;

FIG. 6 is a schematic layout diagram of an OTP memory cell array according to some embodiments;

FIG. 7 is a cross-sectional view taken along line A1-A1′ in FIG. 6;

FIG. 8 is a cross-sectional view taken along line B1-B1′ in FIG. 6;

FIGS. 9A and 9B are graphs showing characteristics of an OTP memory device including multiple program transistors; and

FIG. 10 is a block diagram of a system for explaining an electronic device including an OTP memory device, according to some embodiments.

### DETAILED DESCRIPTION OF THE EMBODIMENTS

A one-time-programmable (OTP) memory cell described herein includes a program transistor and a read transistor. The OTP memory cell may be implemented with peripheral transistors through a complementary metal oxide semiconductor (CMOS) process. The CMOS process may include a fin field effect transistor (FinFET) process of forming a transistor having a three-dimensional structure by using an active fin. The OTP memory cell may electrically program data only once. Although power is no longer supplied to the OTP memory cell, the programmed data may be retained. For example, the OTP memory cell provides an antifuse device that includes a substrate and source and drain regions that are formed in the substrate and are laterally spaced apart from each other to form a channel therebetween. In addition, the antifuse device includes a gate oxide film formed on the channel and a gate formed on the gate oxide film. The antifuse device is programmed by applying power to the gate and at least one of the source and drain regions to break down the gate oxide film, thereby limiting and/or minimizing resistance between the gate and the channel. A read voltage is applied to both ends of the gate oxide film to determine the antifuse state and the resulting current is read. Hereinafter, provided is an OTP memory in which an OTP memory cell includes multiple program transistors and a program operation is performed by a program transistor having the minimum breakdown voltage among the multiple program transistors so that the distribution of the breakdown voltage of OTP memory cells may be narrowed around the minimum breakdown voltage, thereby lowering the programming voltage of the OTP memory cells.

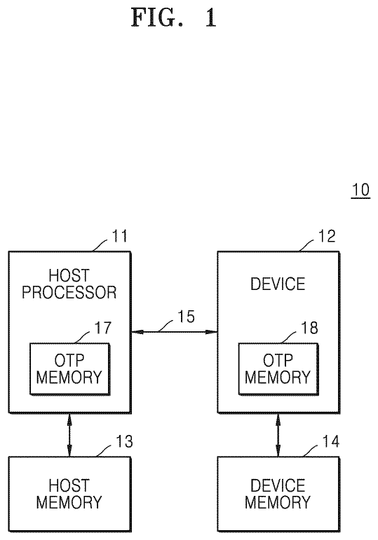

FIG. 1 is a conceptual diagram of a system according to some embodiments. A system 10 of FIG. 1 may include any computing system (or a component included in a computing system) that includes a host processor 11 and a device 12 that communicate with each other. For example, the system 10 may be included in a stationary computing system, such as a desktop computer, a server, a kiosk, and the like, or may be included in a portable computing system, such as a laptop computer, a mobile phone, a wearable device, and the like. In addition, in some embodiments, the system 10 may be included in a system-on-chip (SoC) or system-in-package (SiP) in which the host processor 11 and the device 12 are implemented in one chip or package.

Referring to FIG. 1, the host processor 11 and the device 12 may communicate with each other through a link 15 and may exchange messages and/or data with each other through the link 15. For example, the host processor 11 and the device 12 may communicate with each other based on coherent interconnect technologies, such as a compute express link (CXL) protocol, an XBus protocol, an NVLink protocol, an Infinity Fabric protocol, a cache coherent interconnect for accelerators (CCIX) protocol, a coherent accelerator processor interface (CAPI), and the like.

In some embodiments, the link 15 may support multiple protocols, wherein messages and/or data may be transmitted through the multiple protocols. For example, the link 15 may support CXL protocols including a non-coherent protocol (e.g., CXL.io), a coherent protocol (e.g., CXL.cache), and a memory access protocol (or a memory protocol) (e.g., CXL.mem). The memory protocol may define transactions between a master and a subordinate. For example, the memory protocol may define a transaction from the master towards the subordinate and a transaction from the subordinate towards the master. The coherent protocol may define interactions between the host processor 11 and the device 12. For example, the interface of the coherent protocol may include three channels including a request, a response, and data. The non-coherent protocol may provide a non-coherent load/store interface for input/output (I/O) devices. In some embodiments, the link 15 may support a protocol, such as, but not limited to, peripheral component interconnect (PCI), PCI express (PCIe), universal serial bus (USB), serial advanced technology attachment (SATA), and the like.

The device 12 may refer to any device that provides useful functions to the host processor 11. In some embodiments, the device 12 may correspond to an accelerator in the CXL protocol. For example, software running on the host processor 11 may offload at least a portion of the computing and/or I/O operations to the device 12. In some embodiments, the device 12 may include at least one of a programmable component, such as a graphics processing unit (GPU) or a neural processing unit (NPU), a component providing a fixed function, such as an intellectual property (IP) core, and a reconfigurable component, such as a field programmable gate array (FPGA).

The device 12 may include a physical layer, a multi-protocol multiplexer, an interface circuit, and an accelerator circuit, and may communicate with device memory 14. The accelerator circuit may perform useful functions provided by the device 12 to the host processor 11 and may communicate with the device memory 14 based on a protocol independent of the link 15, e.g., a device-specific protocol. The accelerator circuit may communicate with the host processor 11 through the interface circuit using multiple protocols. The interface circuit may determine one of the multiple protocols, based on the messages and/or data for communication between the accelerator circuit and the host processor 11. The interface circuit may be connected to at least one protocol queue included in the multi-protocol multiplexer and may exchange the messages and/or data with the host processor 11 through the at least one protocol queue. The multi-protocol multiplexer may include multiple protocol queues corresponding to multiple protocols, respectively, supported by the link 15, may arbitrate between communications by different protocols, and may provide selected communications to the physical layer. The physical layer may be connected to a physical layer of the host processor 11 through a single interconnection, a bus, a trace, or the like.

The host processor 11 may include a main processor of the system 10, e.g., a central processing unit (CPU). In some embodiments, the host processor 11 may correspond to a host processor (or a host) of the CXL protocol. The host processor 11 may be connected to a host memory 13 and may include a physical layer, a multi-protocol multiplexer, an interface circuit, a coherence/cache circuit, a bus circuit, at least one core, and an I/O device. The at least one core may execute instructions and may be coupled with the coherence/cache circuit. The coherence/cache circuit may include a cache hierarchy and may communicate with the at least one core and the interface circuit. For example, the coherence/cache circuit may enable communication via two or more protocols including the coherent protocol and the memory access protocol and may include a direct memory access (DMA) circuit. The I/O device may be used to communicate with the bus circuit. For example, the bus circuit may include PCIe logic and the I/O device may include a PCIe I/O device. The interface circuit may enable communication between the device 12 and components of the host processor 11, such as the coherence/cache circuit and the bus circuit. In some embodiments, the interface circuit may enable communication of messages and/or data between the components of the host processor 11 and the device 12 in accordance with multiple protocols, e.g., the non-coherent protocol, the coherent protocol, and the memory protocol. For example, the interface circuit may determine one of the multiple protocols, based on the messages and/or data for communication between the device 12 and the components of the host processor 11. The multi-protocol multiplexer may include at least one protocol queue. The interface circuit may be connected to the at least one protocol queue and may communicate the messages and/or data with the device 12 through the at least one protocol queue.

In some embodiments, the host processor 11 may execute hierarchical software including an operating system (OS) and/or applications running on the OS and may access the host memory 13 and/or the device memory 14 based on virtual memory.

The host processor 11 may program data necessary for operations of the host processor 11 into OTP memory 17. The device 12 may program data necessary for operations of the device 12 into OTP memory 18. The data programmed into each of the OTP memories 17 and 18 may be used to control the operations of the host processor 11 or the device 12. Hereinafter, the OTP memories 17 and 18 may be described in detail through various embodiments. For convenience of description, the OTP memories 17 and 18 may also be referred to as an OTP memory device 20.

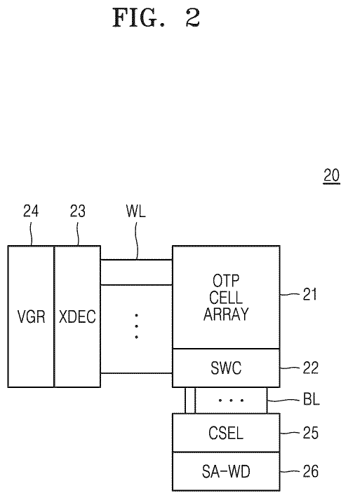

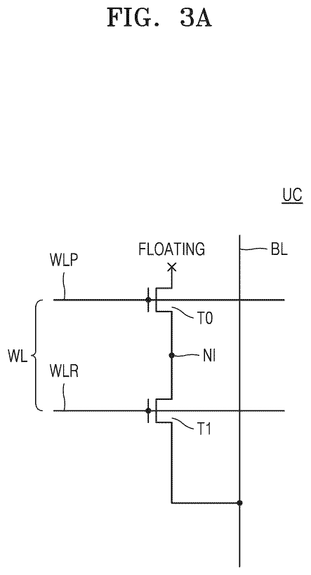

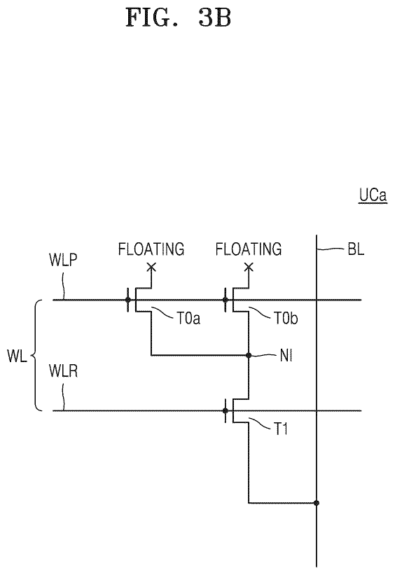

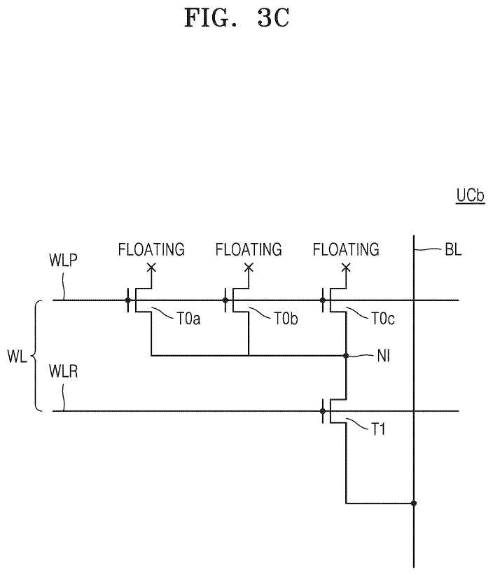

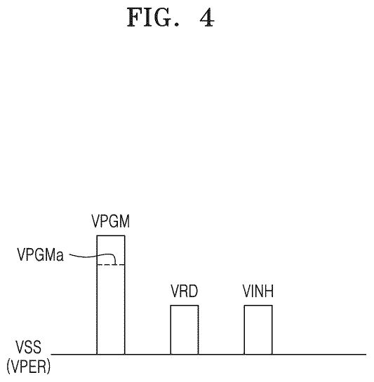

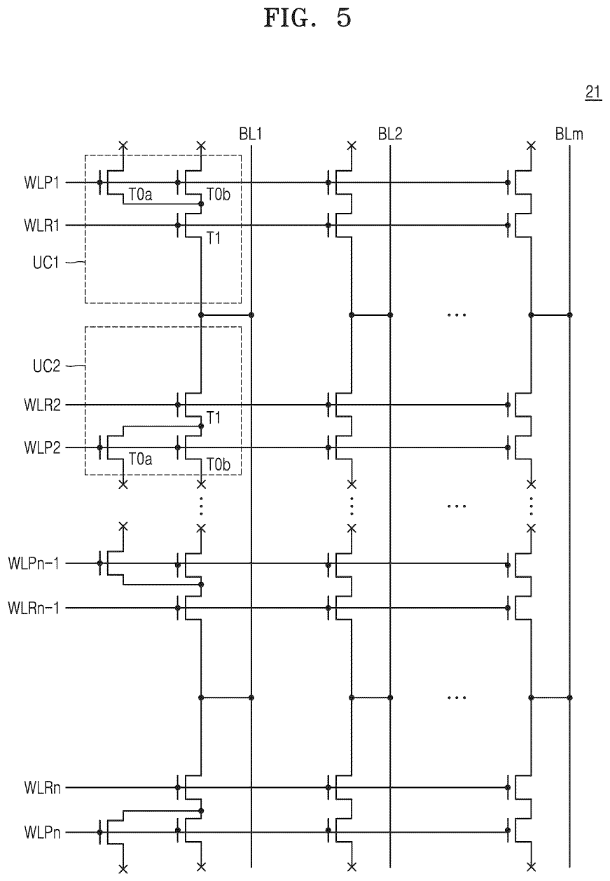

FIG. 2 is a block diagram of an OTP memory device according to some embodiments. FIGS. 3A to 3C are circuit diagrams of an OTP memory cell included in a memory cell array 21 in FIG. 2. FIG. 4 is a diagram illustrating the relationship between operating voltages of the OTP memory cell of FIG. 3A. FIG. 5 is a circuit diagram of the memory cell array 21 in FIG. 2. Hereinafter, suffixes (e.g., a of UCa and b of UCb) attached to the same reference numerals in different diagrams are used to distinguish a plurality of components having similar or same functions.

Referring to FIG. 2, the OTP memory device 20 may include the memory cell array 21, a switching circuit (SWC) 22, a row selection circuit (XDEC) 23, a voltage generation circuit (VGR) 24, a column selection circuit (CSEL) 25, and a write-read circuit (SA-WD) 26. The memory cell array 21 includes a plurality of OTP memory cells connected to each of a plurality of bit lines BL and a plurality of word lines WL. For convenience of description, the term “memory cell array” and the term “OTP cell array” may be used to be equal to each other. Each word line WL may include a voltage word line WLP and a read word lines WLR (FIG. 3A). The SWC 22 may detect a program state of a selected OTP memory cell of the plurality of OTP memory cells in a program mode. Although FIG. 2 illustrates the memory cell array 21 and the SWC 22 separately, the SWC 22 may be included in the memory cell array 21, depending on embodiments.

The XDEC 23 may include a row decoder to select a word line WL corresponding to a row address. The VGR 24 may generate operating voltages applied to the OTP memory cell, e.g., a programming voltage VPGM, a read voltage VRD, and the like (FIG. 4). The CSEL 25 may include a column decoder and a column gate circuit to select a bit line BL corresponding to a column address or a latch address. The column decoder may generate column selection signals based on the column address or the latch address. The column gate circuit may include a plurality of switches that are selectively turned on in response to the column selection signals. One of the switches corresponding to the column address may be turned on to select a bit line BL (FIG. 3A).

The SA-WD 26 may include a read sense amplifier SA and a write driver WD. The SA-WD 26 is connected to bit lines BL through the CSEL 25. The read sense amplifier SA performs a read operation for sensing data stored in the OTP memory cell and providing read data. The write driver WD performs a write operation for storing write data in the OTP memory cell. The write driver WD may be formed integrally with the read sense amplifier SA or may be formed as a separate circuit distinct from the read sense amplifier SA.

Referring to FIG. 3A, an OTP memory cell UC may include a program transistor T0 and a read transistor T1. The program transistor T0 is a type of antifuse and is a structure capable of changing a conductive state. The program transistor T0 is connected between a voltage word line WLP and an intermediate node NI. The read transistor T1 is connected between the intermediate node NI and the bit line BL and a gate electrode is connected to the read word line WLR. The program transistor T0 may have a drain electrode floating, a source electrode connected to the intermediate node NI, and a gate electrode connected to the corresponding voltage word line WLP.

In some embodiments, the antifuse includes a resistive fuse device having electrical properties that are opposite to those of a fuse device and having a high resistance value in an unprogrammed state while having a low resistance value in a programmed state. The antifuse is generally configured with a dielectric between the conductors and is programmed by applying a high voltage through the conductors at both ends of the antifuse for a sufficient time to break the dielectric between the conductors. As the programming result, the conductors at both ends of the antifuse may be shorted and have a low resistance value. The antifuse OTP memory includes a memory that is programmed by applying a high voltage to both ends of a metal oxide semiconductor (MOS) capacitor with a thin gate oxide film to electrically short the fuse. The antifuse OTP memory is capable of implementing a lower-power functional IP (Intellectual Property) due to its small cell area and programming with lower current consumption during programming.

In the OTP memory cell UC, the programming voltage VPGM of a relatively high voltage level may be applied to the voltage word line WLP in a program mode and the read voltage VRD of a lower voltage level than the programming voltage VPGM may be applied to the voltage word line WLP in a read mode, as illustrated in FIG. 4. In the program mode and the read mode, a selection voltage having a voltage level to turn on the read transistor T1 in accordance with the row address may be applied to the read word line WLR. For example, the programming voltage VPGM may be set to about 4 V, which is higher than the power supply voltage (e.g., 2 V) of the OTP memory device 20, and the read voltage VRD may be set to about 1.2 V.

In the program mode, a program permission voltage VPER may be applied to a bit line to which an OTP memory cell to be programmed is connected and a program inhibit voltage VINH greater than the program permission voltage VPER may be applied to a bit line to which the OTP memory cell that is not programmed is connected. For example, the program permission voltage VPER may be set to a ground voltage VSS of 0 V and the program inhibit voltage VINH may be set to about 2 V.

In some embodiments, the program inhibit voltage VINH may be set to the power supply voltage together with the read voltage VRD. The voltage level of the operating voltages, such as the programming voltage VPGM, the read voltage VRD, the program permission voltage VPER, and the program inhibit voltage VINH, may be variously set depending on the characteristics of the OTP memory cell and the configuration of the OTP memory device.

In FIG. 3A, the OTP memory cell UC performs a program operation using the breakdown voltage of the program transistor T0. The distribution of the breakdown voltage of each of the plurality of OTP memory cells included in the OTP memory cell array 21 may be shown wide. This means that the programming voltage VPGM (FIG. 4) applied to the program transistor T0 may be required to have a high voltage level. The VGR 24 that generates the programming voltage VPGM may include a charge-pump circuit and/or a level-shifter circuit. The power consumption due to the operation of the charge pump and the level-shifter generating the high voltage may be significant. To reduce the power consumption, OTP memory cells capable of lowering the programming voltage VPGM are required. FIGS. 3B and 3C show OTP memory cells UCa and UCb including multiple program transistors.

Referring to FIG. 3B, the OTP memory cell UCa may include two program transistors T0a and T0b connected in parallel. The OTP memory cell UCa may include a first program transistor T0a, a second program transistor T0b, and a read transistor T1. Each of the first program transistor T0a and the second program transistor T0b is connected between the voltage word line WLP and the intermediate node NI. The read transistor T1 is connected between the intermediate node NI and the bit line BL and the gate electrode is connected to the read word line WLR. Each of the first program transistor T0a and the second program transistor T0b may have a drain electrode floating, a source electrode connected to the intermediate node NI, and a gate electrode connected to the corresponding voltage word line WLP.

Referring to FIG. 3C, the OTP memory cell UCb may include three program transistors T0a, T0b, and T0c connected in parallel. The OTP memory cell UCb may include a first program transistor T0a, a second program transistor T0b, a third program transistor T0c, and a read transistor T1. Each of the first program transistor T0a, the second program transistor T0b, and the third program transistor T0c is connected between the voltage word line WLP and the intermediate node NI. The read transistor T1 is connected between the intermediate node NI and the bit line BL and the gate electrode is connected to the read word line WLR. Each of the first program transistor T0a, the second program transistor T0b, and the third program transistor T0c may have a drain electrode floating, a source electrode connected to the intermediate node NI, and a gate electrode connected to the corresponding voltage word line WLP.

In FIGS. 3B and 3C, a program operation may be performed by a program transistor having the minimum breakdown voltage among the multiple program transistors T0a, T0b, and T0c. Accordingly, the distribution of the breakdown voltage of the OTP memory cells UCa and UCb may be narrowed down around the minimum breakdown voltage and the programming voltage of the OTP memories UCa and Ucb may be reduced. A programming voltage VPGMa (FIG. 4) of the OTP memory cells UCa and UCb may be reduced, thereby reducing the power consumption of the OTP storage device 20 and increasing the programming efficiency.

Referring to FIG. 5, the memory cell array 21 may include a plurality of OTP memory cells UC1 and UC2 connected to a plurality of read word lines WLR1 to WLRn, a plurality of voltage word lines WLP1 to WLPn, and a plurality of bit lines BL1 to BLm and arranged in an n*m (n and m are positive integers) matrix. Each of the OTP memory cells UC1 and UC2 may include a first program transistor T0a, a second program transistor T0b, and a read transistor T1, like the OTP memory cell UCa in FIG. 3B. A gate of the read transistor T1 may be connected to a corresponding read word line WLRx (x is an integer of 1 or greater and n or less) and a source region of the read transistor T1 may be connected to a corresponding bit line BLy (y is an integer of 1 or greater and m or less). A first terminal of each of the first program transistor T0a and the second program transistor T0b may be connected to a corresponding program word line WLPx and a second terminal of each of the first program transistor T0a and the second program transistor T0b may be connected to a drain region of the read transistor T1. A gate of each of the first program transistor T0a and the second program transistor T0b may be connected to a corresponding voltage word line WLPx as the first terminal, a source region of each of the first program transistor T0a and the second program transistor T0b may be connected to a drain region of the read transistor T1 as the second terminal, and a drain region of each of the first program transistor T0a and the second program transistor T0b may be floating. Although FIG. 5 shows one pair of OTP memory cells UC1 and UC2, the arrangement of unit cells may be implemented in various ways.

In some embodiments, each of the OTP memory cells UC1 and UC2 of the memory cell array 21 may include a first program transistor T0a, a second program transistor T0b, a third program transistor T0c, and a read transistor T1, like the OTP memory cell UCb of FIG. 3C. A gate of the read transistor T1 may be connected to a corresponding read word line WLRx (x is an integer of 1 or greater and n or less) and a source region of the read transistor T1 may be connected to a corresponding bit line BLy (y is an integer of 1 or greater and m or less). A source region of each of the first program transistor T0a, the second program transistor T0b, and the third program transistor T0c may be connected to a drain region of the read transistor T1, and a drain region of each of the first program transistor T0a, the second program transistor T0b, and the third program transistor T0c may be floating.

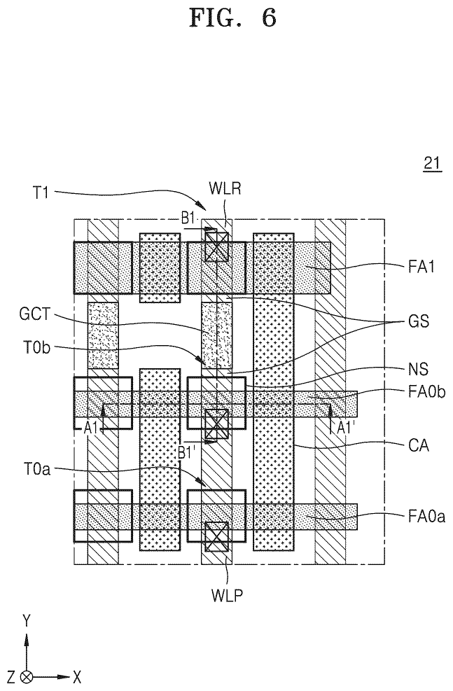

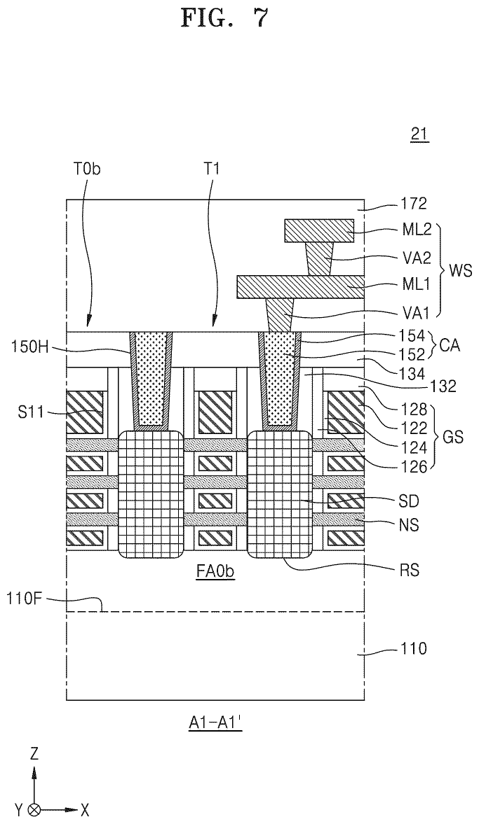

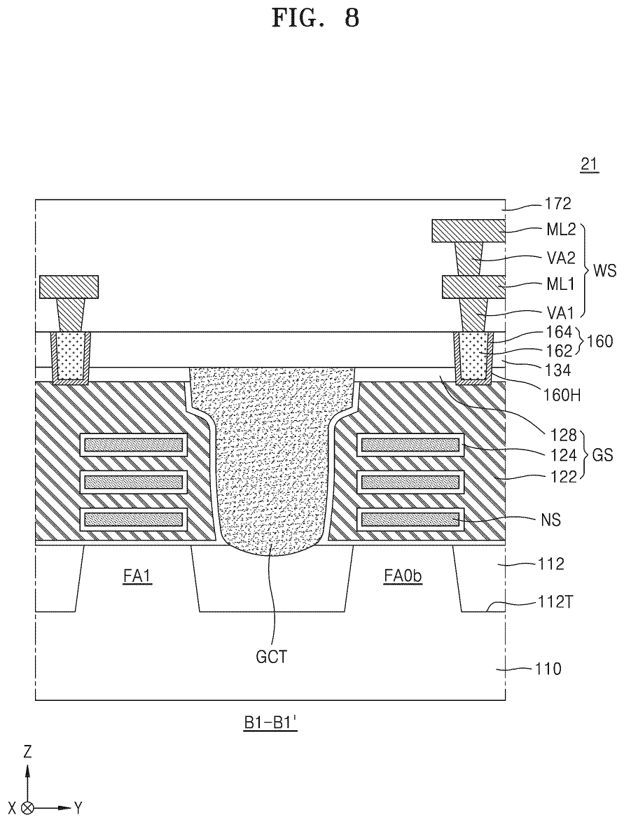

FIG. 6 is a schematic layout diagram of an OTP memory cell array according to some embodiments. FIG. 6 shows a layout of the OTP memory cell UCa of FIG. 3B, FIG. 7 is a cross-sectional view taken along line A1-A1′ in FIG. 6, and FIG. 8 is a cross-sectional view taken along line B1-B1′ in FIG. 6. For convenience of description, those described as top/bottom, upper/lower, up/down, left/right, and the like have been referred to with reference to the directions shown in the drawings. Thus, even the same surface may be referred to as an upper surface or a lower surface, according to the directions shown in the drawings.

Referring to FIGS. 3B, 6, 7, and 8, the OTP memory cell array 21 may include an OTP memory cell including a multi-bridge channel FET (MBCFET) device. However, inventive concepts are not limited thereto. The OTP memory cell array 21 may include a planar FET device, a gate-all-around type FET device, a FinFET device, a two-dimensional material-based FET device such as a MoS₂ semiconductor gate electrode, and the like.

Fin-type active regions FA1, FA0b, and FA0a may be disposed on a first surface 110F of a substrate 110, and a device isolation film 112 may cover lower sidewalls of the fin-type active regions F0b, FA0a, and FA0b. The device isolation film 112 may fill a device isolation trench 112T extending from the first surface 110F of the substrate 110 into the substrate 110. For example, the device isolation film 112 may have a double-layer structure of an interface layer (not shown) and a buried insulating layer (not shown). A read transistor T1 may be arranged in the fin-type active region FA1, a second program transistor T0b may be arranged in the fin-type active region FA0b, and a first program transistor T0a may be arranged in the fin-type active region FA0a.

On the fin-type active regions FA1, FA0b, and FA0a, a plurality of semiconductor patterns NS may be spaced apart from each other in a vertical direction Z. Each of the plurality of semiconductor patterns NS may include a group IV semiconductor, such as Si or Ge, a group IV-IV compound semiconductor, such as SiGe or SiC, or a group III-V compound semiconductor, such as GaAs, InAs, or InP. The plurality of semiconductor patterns NS may have a relatively large width in a second horizontal direction Y and a relatively small thickness in the vertical direction Z. For example, the plurality of semiconductor patterns NS may have a shape of a nanosheet.

A plurality of gate structures GS may extend in the second horizontal direction Y to surround the plurality of semiconductor patterns NS and may be spaced apart from each other in a first horizontal direction X at a first gate interval. Each of the plurality of gate structures GS may include a gate electrode 122, a gate insulating layer 124, a gate spacer 126, and a gate capping layer 128. For example, the gate electrode 122 may extend in the second horizontal direction Y to surround the plurality of semiconductor patterns NS on the fin-type active regions FA1, FA0b, and FA0a. The gate insulating layer 124 may be arranged between the gate electrode 122 and the fin-type active regions FA1, FA0b, and FA0a and between the gate electrode 121 and each semiconductor pattern NS. The gate spacer 126 may be arranged on both sidewalls of the gate electrode 122, and the gate capping layer 128 may extend in the second horizontal direction Y on the gate electrode 122 and the gate insulating layer 124.

In some embodiments, the gate electrode 122 may include doped polysilicon, a metal, a conductive metal nitride, a conductive metal carbide, a conductive metal silicide, or a combination thereof. For example, the gate electrode 122 may include, but not limited to, aluminum (Al), copper (Cu), titanium (Ti), tantalum (Ta), tungsten (W), molybdenum (Mo), tantalum nitride (TaN), nickel silicide (NiSi), cobalt silicide (CoSi), titanium nitride (TiN), tungsten nitride (WN), titanium aluminide (TiAl), titanium aluminum nitride (TiAlN), tantalum carbonitride (TaCN), tantalum carbide (TaC), tantalum silicon nitride (TaSiN), or a combination thereof. In some embodiments, the gate electrode 122 may include a work function metal-containing layer (not shown) and a gap-fill metal film (not shown). The work function metal-containing layer may include at least one metal selected from Ti, W, ruthenium (Ru), niobium (Nb), Mo, hafnium (Hf), nickel (Ni), cobalt (Co), platinum (Pt), ytterbium (Yb), terbium (Tb), dysprosium (Dy), erbium (Er), and palladium (Pd). The gap-fill metal film may include a W film or an Al film. In some embodiments, the gate electrode 122 may include, but not limited to, a stacked-layer structure of TiAlC/TiN/W, a stacked-layer structure of TiN/TaN/TiAlC/TiN/W, or a stacked-layer structure of TiN/TaN/TiN/TiAlC/TiN/W.

In some embodiments, the gate insulating layer 124 may include a silicon oxide film, a silicon oxynitride film, a high-k film having a dielectric constant higher than that of the silicon oxide film, or a combination thereof. The high-k film may include a metal oxide or a metal oxynitride. For example, the high-k film usable as the gate insulating layer 124 may include, but not limited to, hafnium dioxide (HfO₂), hafnium silicate (HfSiO), hafnium silicon oxynitride (HfSiON), hafnium tantalum oxide (HfTaO), hafnium titanium oxide (HfTiO), hafnium zirconium oxide (HfZrO), zirconium dioxide (ZrO₂), aluminum oxide (Al₂O₃), or a combination thereof.

In some embodiments, the gate spacer 126 may include silicon oxide (SiOx), silicon nitride (SiNx), silicon oxynitride (SiOxNy), silicon carbonitride (SiCxNy) silicon oxycarbonitride (SiOxCyNz), or a combination thereof. In some embodiments, the gate capping layer 128 may include SiNx or SiOxNy.

A gate cut insulating pattern GCT may be disposed on the sidewall of the gate electrode 122. The gate cut insulating pattern GCT may be arranged between two gate electrodes 122, which are adjacent to each other in the second horizontal direction Y. At least a portion of the sidewall of the gate cut insulating pattern GCT may be curved. The gate cut insulating pattern GCT may include SiNx.

A recess RS extending into the fin-type active region FA may be formed on both sides of the gate structure GS, and a source/drain region SD may be formed inside the recess RS. The source/drain region SD formed inside the recess RS may be connected to both ends of the plurality of semiconductor patterns NS. The source/drain region SD may have a top surface arranged at a higher level than the upper surface of the top semiconductor pattern NS. The source/drain region SD may have a plurality of inclined sidewalls. For example, the source/drain region SD may have a vertical cross-sectional shape, such as, a hexagon, a pentagon, a rhombus, or a polygon with rounded corners.

In some embodiments, the source/drain region SD may include, but not limited to, a doped SiGe film, a doped Ge film, a doped SiC film, or a doped InGaAs film. The source/drain region SD may be formed by removing a portion of the semiconductor pattern NS on both sides of the gate structure GS to form the recess RS and growing a semiconductor layer filling the recess RS by an epitaxy process. In some embodiments, the source/drain region SD may include a plurality of semiconductor layers having different compositions from each other. For example, the source/drain region SD may include a lower semiconductor layer (not shown), an upper semiconductor layer (not shown), and a capping semiconductor layer (not shown) that sequentially fill the recess RS. For example, the lower semiconductor layer, the upper semiconductor layer, and the capping semiconductor layer each include SiC and may have different contents of Si and C.

An inter-gate insulating layer 132 covering the source/drain region SD may be formed between the gate structures GS. An upper insulating layer 134 may be disposed on the inter-gate insulating layer 132 and the gate structures GS. The inter-gate insulating layer 132 and the upper insulating layer 134 may include SiOx, silicon carbon oxide, or SiOxNy.

A first contact CA may be disposed on the source/drain region SD. For example, the first contact CA may include a contact plug 152 and a conductive barrier layer 154, which are formed inside a first contact hole 150H passing through the inter-gate insulating layer 132 and the upper insulating layer 134. The contact plug 152 may include at least one of W, Co, Mo, Ni, Ru, Cu, Al, a silicide thereof, or an alloy thereof. The conductive barrier layer 154 may include at least one of Ru, Ti, TiN, Ta, TaN, W, titanium silicon nitride (TiSiN), titanium silicide (TiSi), and tungsten silicide (WSi). Although not shown, a metal silicide layer may be further arranged between the first contact CA and the source/drain region SD.

A second contact 160 may be disposed on the gate structure GS. The second contact 160 may include a contact plug 162 and a conductive barrier layer 164 surrounding sidewalls and a bottom surface of the contact plug 162. The second contact 160 may be arranged inside a second contact hole 160H passing through the upper insulating layer 134 and the gate capping layer 128 to expose the upper surface of the gate electrode 122.

A wiring structure WS may be disposed on the upper insulating layer 134. The wiring structure WS may include wiring layers ML1 and ML2 and vias VA1 and VA2. An interlayer insulating film 172 may cover the wiring structure WS on the upper insulating layer 134. For example, the interlayer insulating film 172 may include a plurality of material layers, wherein each of the plurality of material layers may cover the top surface and the bottom surface of each of the wiring layers ML1 and ML2 and surround the sidewalls of the vias VA1 and VA2. In some embodiments, the interlayer insulating film 172 may include an oxide film, a nitride film, or a combination thereof.

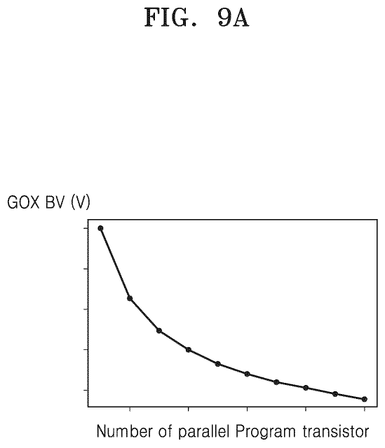

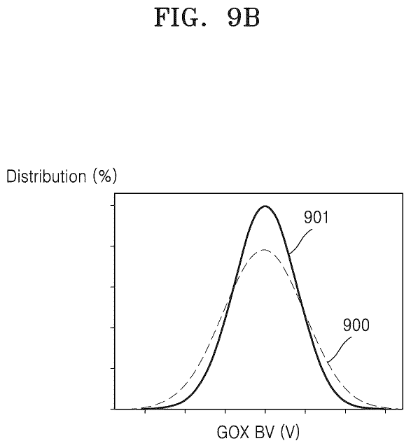

FIGS. 9A and 9B are graphs showing characteristics of an OTP memory device including multiple program transistors.

Referring to FIG. 3B, FIG. 3C, and FIG. 9A, it may be seen that the breakdown voltage of the program transistors T0a, T0b, and T0c decreases as the number of program transistors T0a, T0b, and T0c connected in parallel increases. Referring to FIG. 9B, a breakdown voltage range 900 of one program transistor T0 in FIG. 3A and a breakdown voltage range 901 of multiple program transistors T0a, T0b, and T0c in FIG. 3C are shown. It may be seen that the breakdown voltage range 901 of the multiple program transistors T0a, T0b, and T0c narrows around the minimum breakdown voltage. Accordingly, the programming voltage of the OTP memory cell may be reduced, thereby reducing the power consumption of the OTP storage device and increasing the programming efficiency.

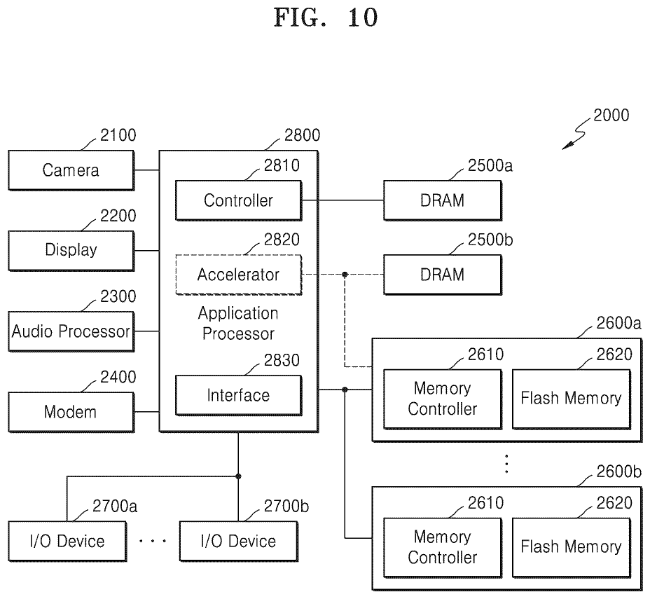

FIG. 10 is a block diagram of a system for explaining an electronic device including an OTP memory device, according to some embodiments.

Referring to FIG. 10, a system 2000 may include a camera 2100, a display 2200, an audio processor 2300, a modem 2400, DRAMs 2500a and 2500b, flash memories 2600a and 2600b, I/O devices 2700a and 2700b, and an application processor (AP) 2800. The system 2000 may be implemented as a laptop computer, a mobile phone, a smartphone, a tablet personal computer (PC), a wearable device, a healthcare device, or an Internet Of Things (IoT) device. In addition, the system 2000 may be implemented as a server or a PC.

The camera 2100 may capture a still image or a video under the control by a user and may store or transmit the captured image/video data to the display 2200. The audio processor 2300 may process audio data included in the flash memories 2600a and 2600b or content of a network. The modem 2400 may modulate and transmit a signal for wired/wireless data transmission and reception to a receiver, and the receiver may demodulate the signal to recover the original signal. The I/O devices 2700a and 2700b may include devices that provide digital input and/or output functions, such as universal serial bus (USB) or storage, digital cameras, secure digital (SD) cards, digital versatile discs (DVDs), network adapters, touch screens, and the like.

The AP 2800 may control the overall operation of the system 2000. The AP 2800 may include a control block 2810, an accelerator block or accelerator chip 2820, and an interface block 2830. The AP 2800 may control the display 2200 such that a portion of content stored in the flash memories 2600a and 2600b is displayed on the display 2200. When user input is received through the I/O devices 2700a and 2700b, the AP 2800 may perform the control operation corresponding to the user input. The AP 2800 may include the accelerator block that is a dedicated circuit for artificial intelligence (AI) data computation or may include the accelerator chip 2820 separate from the AP 2800. The DRAM 2500b may be additionally mounted on the accelerator block or the accelerator chip 2820 OK. The accelerator block 2820 OK, which is a functional block professionally performing a specific function of the AP 2800, may include a GPU that is a functional block professionally performing graphics data processing, an NPU that is a block professionally performing AI calculation and inference, and a data processing unit (DPU) that is a block professionally performing data transmission. In an embodiment, an image captured by a user through the camera 2100 may be signal-processed and stored in the DRAM 2500b. The accelerator block or the accelerator chip 2820 may perform AI data computation for recognizing data by using the data stored in the DRAM 2500b and the function used for inference.

The system 2000 may include the plurality of DRAMs 2500a and 2500b. The AP 2800 may control the DRAMs 2500a and 2500b through command and mode register (MRS) settings conforming to the joint electron device engineering council (JEDEC) standard or may communicate with the DRAMs 2500a and 2500b by setting a DRAM interface protocol to use company-specific functions, such as low voltage/high speed/reliability, and cyclic redundancy check (CRC)/error correction code (ECC) functions. For example, the AP 2800 may communicate with the DRAMs 2500a and 2500b through an interface conforming to the JEDEC standard, such as LPDDR4 and the LPDDR5, and the accelerator block 2820 may communicate with the DRAMs 2500a and 2500b by setting a new DRAM interface protocol to control the DRAM 2500b for an accelerator having a bandwidth higher than that of the DRAM 2500a.

FIG. 10 shows only the DRAMs 2500a and 2500b but is not limited thereto. Any memory, such as PRAM, SRAM, MRAM, RRAM, FRAM, or Hybrid RAM, may be used as long as the memory satisfies the bandwidth, reaction rate, and voltage conditions of the AP 2800 or the accelerator block or the accelerator chip 2820. The DRAMs 2500a and 2500b may have a latency and a bandwidth relatively less than that of the I/O devices 2700a and 2700b or the flash memories 2600a and 2600b. The DRAMs 2500a and 2500b may be initialized when the system 2000 is powered on. The OS and application data may be loaded and used as temporary storage locations of the OS and the application data or used as execution spaces of various software codes.

In the DRAMs 2500a and 2500b, addition/subtraction/multiplication/division arithmetic operations and vector operations, address operations, or fast Fourier transform (FFT) operations may be performed. In addition, within the DRAMs 2500a and 2500b, a function used for inference may be performed. The inference may be performed by a deep learning algorithm using an artificial neural network. The deep learning algorithm may include training a model through various data and inferring data with the trained model.

The system 2000 may include the plurality of flash memories 2600a and 2600b or a plurality of storages having a capacity greater than that of the DRAMs 2500a and 2500b. The accelerator block or the accelerator chip 2820 may perform the training and the AI data computation by using the flash memories 2600a and 2600b. In an embodiment, the flash memories 2600a and 2600b may include a memory controller 2610 and a flash memory device 2620. The training and the inference AI data computation performed by the AP 2800 and/or the accelerator chip 2820 may be performed more efficiently by using a computing device provided in the memory controller 2610. The flash memories 2600a and 2600b may store a photograph taken through the camera 2100 or may store data transmitted to a data network. For example, augmented reality/virtual reality, high definition (HD), or ultra-high definition (UHD) content may be stored in the flash memories 2600a and 2600b.

The components of the system 2000 may include the OTP memory devices described with reference to FIGS. 1 to 9B. The OTP memory device includes the plurality of OTP memory cells, each of which may include a first program transistor having a first breakdown voltage, a second program transistor having a second breakdown voltage, and a read transistor connected to the first program transistor and the second program transistor. Each of the first program transistor, the second program transistor, and the read transistor may include a fin-type active region extending in a first direction on a substrate, a plurality of semiconductor patterns spaced apart from an upper surface of the fin-type active region and having a channel region, and a gate electrode arranged between each of the plurality of semiconductor patterns and extending in a second direction intersecting the first direction on the fin-type active region. A first fin-type active region of the first program transistor, a second fin-type active region of the second program transistor, and a third fin-type active region of the read transistor may be separated from each other. Each of the plurality of OTP memory cells may be configured to be programmed by a lower voltage among the first breakdown voltage and the second breakdown voltage.

Any or all of the elements described with reference to FIG. 10 may communicate with any or all other elements described with reference to FIG. 10. For example, any element may engage in one-way and/or two-way and/or broadcast communication with any or all other elements in FIG. 10, to transfer and/or exchange and/or receive information such as but not limited to data and/or commands, in a manner such as in a serial and/or parallel manner, via a bus such as a wireless and/or a wired bus (not illustrated). The information may be in encoded various formats, such as in an analog format and/or in a digital format.

One or more of the elements disclosed above may include or be implemented in processing circuitry such as hardware including logic circuits; a hardware/software combination such as a processor executing software; or a combination thereof. For example, the processing circuitry more specifically may include, but is not limited to, a central processing unit (CPU), an arithmetic logic unit (ALU), a digital signal processor, a microcomputer, a field programmable gate array (FPGA), a System-on-Chip (SoC), a programmable logic unit, a microprocessor, application-specific integrated circuit (ASIC), etc.

While inventive concepts have been particularly shown and described with reference to embodiments thereof, it will be understood that various changes in form and details may be made therein without departing from the spirit and scope of the following claims.

What is claimed is:

1. A one-time-programmable (OTP) memory device, comprising:
a plurality of OTP memory cells on a substrate,
wherein each of the plurality of OTP memory cells includes a first program transistor having a first breakdown voltage, a second program transistor having a second breakdown voltage, and a read transistor connected to the first program transistor and the second program transistor,
wherein each of the read transistor, the first program transistor, and the second program transistor includes
a fin-type active region extending in a first direction on the substrate,
a plurality of semiconductor patterns spaced apart from an upper surface of the fin-type active region and having a channel region, and
a gate electrode extending in a second direction on the fin-type active region and arranged between each of the plurality of semiconductor patterns,
wherein the second direction intersects the first direction,
wherein the fin-type active region of the first program transistor is a first fin-type active region, the fin-type active region of the second program transistor is a second fin-type active region, and the fin-type active region of the read transistor is a third fin-type active region,
wherein the first fin-type active region of the first program transistor, the second fin-type active region of the second program transistor, and the third fin-type active region of the read transistor are separated from each other.

2. The OTP memory device of claim 1, wherein each of the plurality of OTP memory cells is configured to be programmed by a lower voltage among the first breakdown voltage and the second breakdown voltage.

3. The OTP memory device of claim 1, wherein
the gate electrode of the first program transistor is a first gate electrode,
the gate electrode of the second program transistor is a second gate electrode,
the first program transistor comprises the first gate electrode, a first source electrode connected to a first source region, and a first drain electrode connected to a first drain region,
the second program transistor comprises the second gate electrode, a second source electrode connected to a second source region, and a second drain electrode connected to a second drain region,
the first gate electrode and the second gate electrode are connected to each other, and
the first source electrode and the second source electrode are connected to each other.

4. The OTP memory device of claim 3, wherein the first drain electrode and the second drain electrode are floating.

5. The OTP memory device of claim 3, further comprising:
a voltage word line connected to the first gate electrode and the second gate electrode, wherein
the voltage word line is configured to provide a same voltage to the first gate electrode and the second gate electrode.

6. The OTP memory device of claim 3, further comprising:
a bit line, wherein
the gate electrode of the read transistor is a third gate electrode,
the read transistor comprises the third gate electrode, a third source electrode connected to a third source region, and a third drain electrode connected to a third drain region,
the third drain electrode is connected to the first source electrode and the second source electrode, and
the third source electrode is connected to the bit line.

7. The OTP memory device of claim 6, further comprising:
a read word line connected to the third gate electrode.

8. The OTP memory device of claim 6, wherein the bit line is sensed to determine a state of the first program transistor or the second program transistor.

9. The OTP memory device of claim 1, wherein
each of the plurality of OTP memory cells further comprises a third program transistor having a third breakdown voltage, and
each of the plurality of OTP memory cells is configured to be programmed by a lower voltage among the first breakdown voltage, the second breakdown voltage, and the third breakdown voltage.

10. The OTP memory device of claim 1, wherein the first program transistor, the second program transistor, and the read transistor each comprise an N-type metal oxide semiconductor (NMOS) transistor.

11. A one-time-programmable (OTP) memory device, comprising:
a plurality of OTP memory cells on a substrate,
wherein each of the plurality of OTP memory cells comprises
a first program transistor having a first breakdown voltage,
a second program transistor having a second breakdown voltage, and
a read transistor connected to the first program transistor and the second program transistor,
wherein each of the read transistor, the first program transistor, and the second program transistor comprises
a fin-type active region extending in a first direction on the substrate,
a plurality of semiconductor patterns spaced apart from an upper surface of the fin-type active region and having a channel region, and
a gate electrode extending in a second direction on the fin-type active region and arranged between each of the plurality of semiconductor patterns,
wherein the second direction intersects the first direction, and
wherein each of the plurality of OTP memory cells is configured to be programmed by a lower voltage among the first breakdown voltage and the second breakdown voltage.

12. The OTP memory device of claim 11, wherein
the gate electrode of the first program transistor is a first gate electrode,
the gate electrode of the second program transistor is a second gate electrode,
the first program transistor comprises the first gate electrode, a first source electrode connected to a first source region, and a first drain electrode connected to a first drain region,
the second program transistor comprises the second gate electrode, a second source electrode connected to a second source region, and a second drain electrode connected to a second drain region, and
the first gate electrode and the second gate electrode are connected to each other, and the first source electrode and the second source electrode are connected to each other.

13. The OTP memory device of claim 12, wherein the first drain electrode and the second drain electrode are floating.

14. The OTP memory device of claim 12, further comprising:
a voltage word line connected to the first gate electrode and the second gate electrode and configured to provide a same voltage thereto.

15. The OTP memory device of claim 12, further comprising:
a bit line, wherein
the gate electrode of the read transistor is a third gate electrode,
the read transistor comprises the third gate electrode, a third source electrode connected to a third source region, and a third drain electrode connected to a third drain region,
the third drain electrode is connected to the first source electrode and the second source electrode, and
the third source electrode is connected to the bit line.

16. The OTP memory device of claim 15, further comprising:
a read word line connected to the third gate electrode.

17. The OTP memory device of claim 15, wherein the bit line is sensed to determine a state of the first program transistor or the second program transistor.

18. The OTP memory device of claim 11, wherein the first program transistor, the second program transistor, and the read transistor comprise an N-type metal oxide semiconductor (NMOS) transistor.

19. The OTP memory device of claim 11, wherein
each of the plurality of OTP memory cells further comprises a third program transistor having a third breakdown voltage, and
each of the plurality of OTP memory cells is configured to be programmed by a lower voltage among the first breakdown voltage, the second breakdown voltage, and the third breakdown voltage.

20. The OTP memory device of claim 19, wherein a first fin-type active region of the first program transistor, a second fin-type active region of the second program transistor, a third fin-type active region of the third program transistor, and a fourth fin-type active region of the read transistor are separated from each other.
